(19) United States
(12) Patent Application Publication
(10) Pub. No.: US 2014/0001613 A1
(43) Pub. Date: Jan. 2, 2014

(54) SEMICONDUCTOR PACKAGE

(71) Applicant: Job HA, Suwon (KR)

(72) Inventor: Job HA, Suwon (KR)

(73) Assignee: SAMSUNG ELECTRO-MECHANIC CO., LTD., Suwon (KR)

(21) Appl. No.: 13/603,654

(22) Filed: Sep. 5, 2012

(30) Foreign Application Priority Data
Jun. 29, 2012 (KR) 10-2012-0070565

(51) Int. Cl. H01L 23/495

(52) U.S. Cl. 257/675; 257/E23.051

(57) ABSTRACT

There is provided semiconductor package including: an internal lead having at least one electronic component mounted on a surface thereof; a heat sink disposed below the internal lead; a molded portion sealing the at least one electronic component, the internal lead and the heat sink; an external lead extended from the internal lead and protruding outwardly from the molded portion in a radial direction; a heat radiating member attached to the heat sink and a surface of the molded portion; and an insulating coating film formed on a surface of the external lead.

### CROSS-REFERENCE TO RELATED APPLICATIONS

This application claims the priority of Korean Patent Application No. 10-2012-0070565 filed on Jun. 29, 2012, in the Korean Intellectual Property Office, the disclosure of which is incorporated herein by reference.

### BACKGROUND OF THE INVENTION

1. Field of the Invention

The present invention relates to a semiconductor package, and more particularly, to a semiconductor package having improved isolation characteristics.

2. Description of the Related Art

A semiconductor package includes a lead frame, power semiconductor elements mounted on the lead frame, and a molded portion molding an external portion of each element using a resin, or the like.

In general, a heat sink is used in order to radiate heat generated due to high voltage applied to a semiconductor package outwardly therefrom. However, in the case in which the heat sink is added to the semiconductor package, an electrical short-circuit may occur between the lead frame and the heat sink.

Therefore, a predetermined isolation distance should be secured between the lead frame and the heat sink in order to prevent the occurrence of an electrical short-circuit therebetween.

Since isolation distance may be divided into an isolation clearance distance and an isolation creepage distance, the semiconductor package needs to have a sufficient isolation clearance distance and a sufficient isolation creepage distance according to a rated voltage.

As an operating voltage of the power semiconductor element becomes larger, these isolation distances further increase. Therefore, a size of the semiconductor package also increases.

In accordance with demand for miniaturization and lightness of the semiconductor package, research into a semiconductor package which is not limited in light of an isolation distance, without an increase in a size thereof, has been demanded.

The Related Art Document (Patent Document 1) discloses a semiconductor package having a spacer interposed between a heat sink and a heat radiating fin in order to secure a sufficient isolation clearance distance therebetween.

### RELATED ART DOCUMENT

(Patent Document 1) Japanese Patent Laid-Open Publication No. 2005-033123

### SUMMARY OF THE INVENTION

An aspect of the present invention provides a semiconductor package which is not limited in light of an isolation clearance distance and an isolation creepage distance.

According to an aspect of the present invention, there is provided a semiconductor package including: an internal lead having at least one electronic component mounted on a surface thereof; a heat sink disposed below the internal lead; a molded portion sealing the at least one electronic component, the internal lead and the heat sink; an external lead extended from the internal lead and protruding outwardly from the molded portion in a radial direction; a heat radiating member attached to the heat sink and a surface of the molded portion; and an insulating coating film formed on a surface of the external lead.

The external lead may be bent and extended upwardly at an end thereof, protruding outwardly from the molded portion in the radial direction.

The insulating coating film may be formed on the surface of the external lead except for portions thereof mounted on an external substrate.

The surface of the molded portion to which the heat radiating member is attached may be provided with a concavo-convex portion.

A surface of the heat radiating member facing the external lead may be provided with an insulating sheet.

The insulating coating film may be formed on a portion of the surface of the external lead facing the heat radiating member.

The heat radiating member may have a surface area larger than that of the heat sink.

The insulating coating film and the heat radiating member may have an insulating spacer provided therebetween.

According to another aspect of the present invention, there is provided a semiconductor package including: an internal lead having at least one electronic component mounted on a surface thereof; a heat sink disposed below the internal lead; a molded portion sealing the at least one electronic component, the internal lead and the heat sink; an external lead extended from the internal lead and protruding outwardly from the molded portion in a radial direction; a heat radiating member attached to the heat sink and the molded portion; and an insulating resin provided between the external lead and the heat radiating member and sealing a portion of the external lead.

According to another aspect of the present invention, there is provided a semiconductor package including: an internal lead having at least one electronic component mounted on a surface thereof; a heat sink disposed below the internal lead; a molded portion sealing the at least one electronic component, the internal lead and the heat sink; an external lead extended from the internal lead and protruding outwardly from the molded portion in a radial direction; a heat radiating member attached to the heat sink and the molded portion; and an insulating resin entirely sealing the molded portion while allowing a portion of the external lead to protrude therefrom.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a schematic cross-sectional view showing a semiconductor package according to a first embodiment of the present invention;

FIG. 2 is a schematic cross-sectional view showing a semiconductor package according to a second embodiment of the present invention;

FIG. 3 is a schematic cross-sectional view showing a semiconductor package according to a third embodiment of the present invention;

FIG. 4 is a schematic cross-sectional view showing a semiconductor package according to a fourth embodiment of the present invention;

FIG. 5 is a schematic cross-sectional view showing a semiconductor package according to a fifth embodiment of the present invention;

FIG. 6 is a schematic cross-sectional view showing a semiconductor package according to a sixth embodiment of the present invention;

FIG. 7 is a schematic cross-sectional view showing a method of filling an insulating resin in the semiconductor package according to the sixth embodiment of the present invention; and

FIG. 8 is a schematic cross-sectional view showing a semiconductor package according to a seventh embodiment of the present invention.

### DETAILED DESCRIPTION OF THE EMBODIMENTS

Embodiments of the present invention will be described in detail with reference to the accompanying drawings. The invention may, however, be embodied in many different forms and should not be construed as being limited to the embodiments set forth herein. Rather, these embodiments are provided so that this disclosure will be thorough and complete, and will fully convey the scope of the invention to those skilled in the art.

In the drawings, the shapes and dimensions of elements may be exaggerated for clarity, and the same reference numerals will be used throughout to designate the same or like elements.

Terms with respect to directions will be first defined. An outer or inner radial direction refers to a direction from the center of a molded portion 140 toward an outer surface thereof or a direction opposite thereto, and an upward or downward direction refers to a direction from a heat radiating member 150 towards a lead frame 120 or a direction opposite thereto.

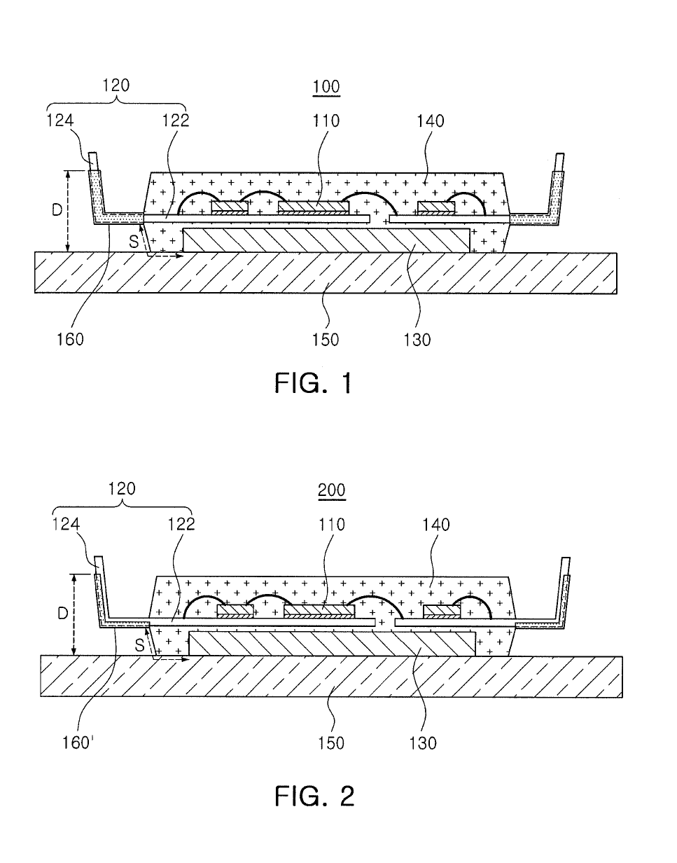

FIG. 1 is a schematic cross-sectional view showing a semiconductor package according to a first embodiment of the present invention.

Referring to FIG. 1, a semiconductor package 100 according to the first embodiment of the present invention may include electronic components 110, a lead frame 120, a heat sink 130, a molded portion 140, and a heat radiating member 150.

The electronic component 110 may include various electronic elements such as a passive element and an active element, and any electronic elements capable of being mounted on the lead frame 120 or embedded in the lead frame 120 may be used.

That is, the electronic component 110 according to the first embodiment of the present invention may include at least one active element such as a semiconductor chip and various passive elements.

Meanwhile, in the first embodiment of the present invention, the semiconductor chip may be electrically connected to the lead frame 120 through a bonding wire, as shown in FIG. 1.

The bonding wire may be formed of a metal material, for example, aluminum (Al), gold (Au), or an alloy thereof.

However, the present invention is not limited thereto, but may be modified in various forms. For example, the semiconductor chip may be manufactured in flip chip form and be then electrically connected to the lead frame 120 through flip chip bonding, as needed.

The lead frame 120 may include a plurality of leads, and each lead may include an external lead 124 connected to an external substrate (not shown) and an internal lead 122 connected to the electronic component 110.

That is, the external lead 124 indicates a portion exposed to the outside of the molded portion 140, and the internal lead 122 indicates a portion disposed within the molded portion 140.

Here, the external lead 124 may protrude from the molded portion 140 in the outer radial direction and be bent and extended upwardly at the protruding end thereof.

The electronic components 110 may be mounted on one surface of the internal lead 122 and be electrically connected to each other through the bonding wire.

The lead frame 120 may include mounting electrodes or circuit patterns (not shown) formed on an upper surface thereof, wherein the mounting electrodes 20 are formed for mounting the electronic components 110 thereon and the circuit patterns (not shown) electrically interconnect the mounting electrodes.

The heat sink 130 may be disposed below the lead frame 120 in order to efficiently radiate heat generated from the semiconductor package 100 according to the first embodiment of the present invention.

That is, the heat sink 130 may be disposed below the lead frame 120 so that one surface thereof faces a surface of the lead frame 120 opposite to one surface thereof on which the electronic components 110 are mounted.

The heat sink 130 may be formed of a metal having high thermal conductivity in order to improve heat radiating characteristics of the semiconductor package 100.

One surface of the heat sink 130 may face the other surface of the lead frame 120, and the other surface thereof may contact one surface of the heat radiating member 150 to be described below.

Since the semiconductor package 100 using a high voltage generates a large amount of heat, the separate heat radiating member 150 may be additionally attached to the heat sink 130.

The heat radiating member 150 may be formed of a metal having high thermal conductivity, similar to the heat sink 130, and may have a surface area larger than that of the heat sink 130.

One surface of the heat radiating member 150 contacting the other surface of the heat sink 130 may face the external lead 124 protruding outwardly from the molded portion 140 to be described below.

The molded portion 140 may be provided between the electronic components 110 mounted on the internal lead 122 to prevent the occurrence of an electrical short-circuit between the electronic components 110. In addition, the molded portion 140 may fix the electronic components 110 while enclosing the electronic components 110, thereby securely protecting the electronic components 110 from external impacts.

Specifically, the molded portion 140 may seal a portion of the lead frame 120, the electronic components 110, and the heat sink 130.

The molded portion 140 may cover and seal the electronic components 110 and the internal lead 122 of the lead frame 120 to which the electronic components 110 are connected, thereby protecting the electronic components 110 from an external environment.

In addition, the molded portion 140 may fix the electronic components 110 while enclosing the electronic components 110, thereby securely protecting the electronic components 110 from external impacts.

Here, the molded portion 140 may be formed to allow the other surface of the heat sink 130 to be exposed outwardly.

That is, the molded portion 140 may seal the lead frame 120 and the heat sink 130 as well as the electronic components 110 while allowing the other surface of the heat sink 130 to be exposed outwardly.

The separate heat radiating member 150 may be attached to one surface of the molded portion 140 and the other surface of the heat sink 130 in order to efficiently radiate heat.

The molded portion 140 may be formed by a molding method. In this case, a silicone gel, an epoxy mold compound (EMC), a polyimide, or the like, having high thermal conductivity may be used as a material of the molded portion 140.

However, the present invention is not limited thereto. That is, various methods such as a method of compressing a B-stage resin, and the like, may be used for forming the molded portion 140, as needed.

The molded portion 140 may be formed between the lead frame 120 and the heat sink 130 so as to allow them to be electrically insulated from each other.

The heat radiating member 150 may be made of a metal having excellent conductivity. Therefore, in the case in which the electronic components 110 operate at a high voltage, an electrical short-circuit may occur between the external lead 124 and the heat radiating member 150 of the semiconductor package 100 according to the embodiment of the prevent invention.

Therefore, an appropriate isolation distance needs to be secured between the external lead 124 and the heat radiating member 150 in order to prevent the occurrence of an electrical short-circuit therebetween.

That is, an appropriate isolation clearance distance D and isolation creepage distance S need to be secured between the external lead 124 protruding outwardly from the molded portion 140 and the heat radiating member 150.

To this end, the surface of the external lead 124 may be provided with an insulating coating film 160 which may be applied to entirely enclose the surface of the external lead 124.

The external lead 124 may be mounted on an external substrate such as a printed board assembly (PBA), or the like. In this case, the insulating coating film 160 may be formed on portions of the external lead 124, except for portions of the external lead 124 mounted on the external substrate.

The insulating coating film 160 covers the surface of the external lead 124, whereby insulation characteristics may be secured at a distance shorter than the insulation clearance distance D and the insulation creepage distance S defined by a rated voltage.

FIG. 2 is a schematic cross-sectional view showing a semiconductor package according to a second embodiment of the present invention.

Referring to FIG. 2, a semiconductor package 200 according to the second embodiment of the present invention is the same as the semiconductor package 100 described with reference to FIG. 1, except for an insulating coating film 160′. Therefore, a description of the same components except for the insulating coating film 160′ will be omitted.

A surface of the external lead 124 may be provided with the insulating coating film 160′. The insulating coating film 160′ may be formed on a surface of the external lead 124 facing the heat radiating member 150 among surfaces of the external lead 124.

The insulating coating film 160′ covers the surface of the external lead 124 facing the heat radiating member 150, whereby insulation characteristics may be secured at a distance shorter than the insulation clearance distance D and the insulation creepage distance S defined by a rated voltage.

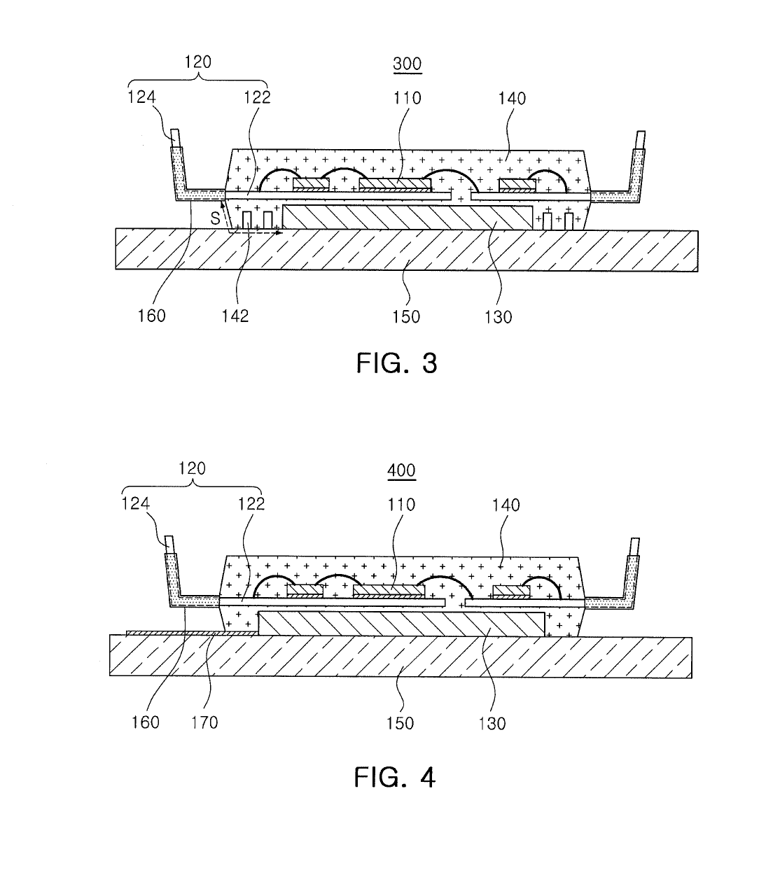

FIG. 3 is a schematic cross-sectional view showing a semiconductor package according to a third embodiment of the present invention.

Referring to FIG. 3, a semiconductor package 300 according to the third embodiment of the present invention is the same as the semiconductor package 100 described with reference to FIG. 1, except for the molded portion 140. Therefore, a description of the same components except for the molded portion 140 will be omitted.

The molded portion 140 may be provided between the electronic components 110 mounted on the internal lead 122 to prevent the occurrence of an electrical short-circuit between the electronic components 110. In addition, the molded portion 140 may fix the electronic components 110 while enclosing the electronic components 110, thereby securely protecting the electronic components 110 from external impacts.

Specifically, the molded portion 140 may seal a portion of the lead frame 120, the electronic components 110, and the heat sink 130.

Here, the molded portion 140 may be formed to allow the other surface of the heat sink 130 to be exposed outwardly.

That is, the molded portion 140 may seal the lead frame 120 and the heat sink 130 as well as the electronic components 110 while allowing the other surface of the heat sink 130 to be exposed outwardly.

The separate heat radiating member 150 may be attached to one surface of the molded portion 140 and the other surface of the heat sink 130 in order to efficiently radiate heat.

Here, one surface of the molded portion 140 to which the heat radiating member is attached may be provided with a concavo-convex portion 142.

As shown in FIG. 3, the concavo-convex portion 142 may include at least one convex portion and at least one concave portion which are alternately formed.

The insulation creepage distance S between the external lead 124 and the heat radiating member 150 may be sufficiently secured by the concavo-convex portion 142. In addition, the insulating coating film 160 is formed on the surface of the external lead 124, whereby insulation characteristics may be secured at a distance shorter than the insulation clearance distance D defined by a rated voltage.

FIG. 4 is a schematic cross-sectional view showing a semiconductor package according to a fourth embodiment of the present invention.

Referring to FIG. 4, a semiconductor package 400 according to the fourth embodiment of the present invention is the same as the semiconductor package 100 described with reference to FIG. 1, except for an insulating sheet 170. Therefore, a description of the same components except for the insulating sheet 170 will be omitted.

The insulating sheet 170 may be provided on a portion of one surface of the heat radiating member 150 attached to one surface of the molded portion 140 and the other surface of the heat sink 130 and facing the external lead 124 protruding outwardly from the molded portion 140 in the outer radial direction.

The insulating sheet 170 may be fixed to one surface of the heat radiating member 150 using an adhesive, or the like.

The insulating sheet 170 covers one surface of the heat radiating member 150 facing the external lead 124, whereby the insulation clearance distance D and the insulation creepage distance S may be more effectively secured.

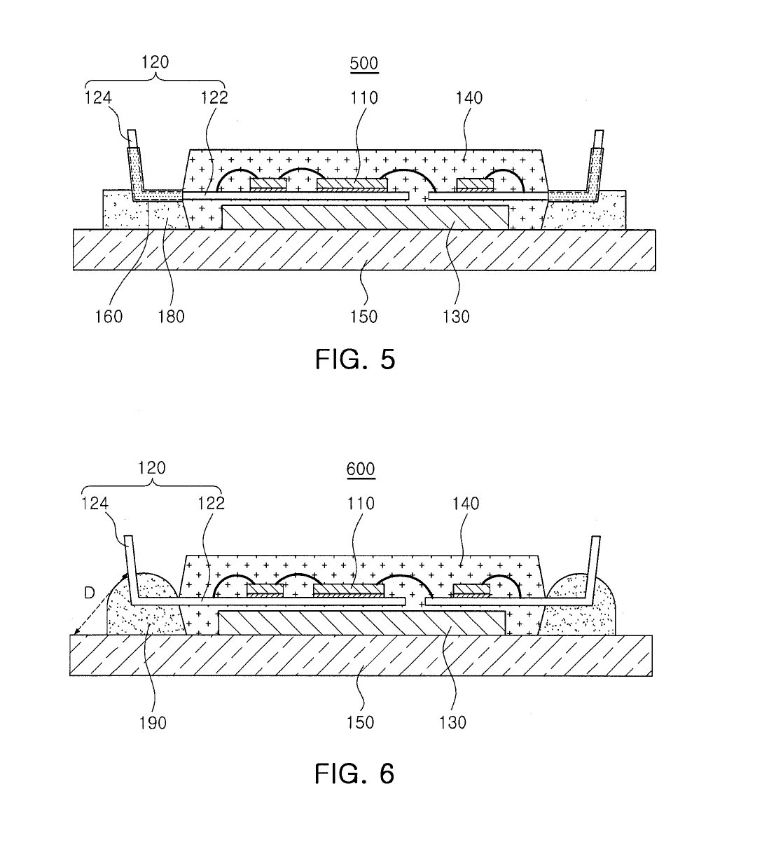

FIG. 5 is a schematic cross-sectional view showing a semiconductor package according to a fifth embodiment of the present invention.

Referring to FIG. 5, a semiconductor package 500 according to the fifth embodiment of the present invention is the same as the semiconductor package 100 described with reference to FIG. 1, except for an insulating spacer 180. Therefore, a description of the same components except for the insulating spacer 180 will be omitted.

The external lead 124 protruding outwardly from the molded portion 140 in the outer radial direction and the heat radiating member 150 may have a predetermined space formed therebetween, and the space may be filled with the insulating spacer 180.

The insulating spacer 180 may be formed of a polymer resin based material, a silicon rubber based material, an inorganic oxide based material, or the like.

The insulating spacer 180 fills the space between the external lead 124 and the heat radiating member 150, such that a heat radiating area of the heat radiating member 150 may increase without a limitation in the insulation clearance distance D.

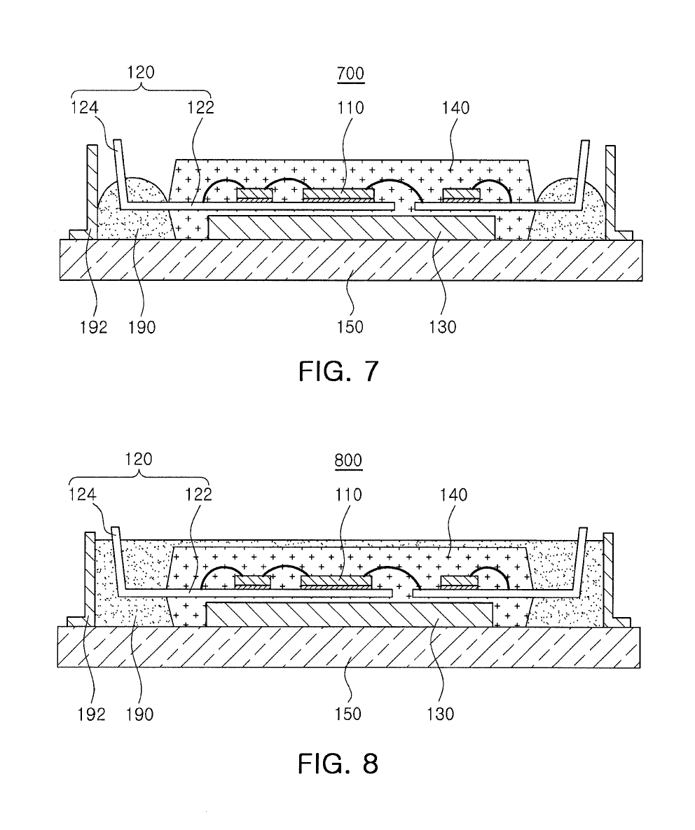

FIG. 6 is a schematic cross-sectional view showing a semiconductor package according to a sixth embodiment of the present invention, and FIG. 7 is a schematic cross-sectional view showing a method of filling an insulating resin in the semiconductor package according to the sixth embodiment of the present invention.

Referring to FIGS. 6 and 7, a semiconductor package 600 according to the sixth embodiment of the present invention is the same as the semiconductor package 100 described with reference to FIG. 1, except for an insulating resin 190. Therefore, a description of the same components except for the insulating resin 190 will be omitted.

The external lead 124 protruding outwardly from the molded portion 140 in the outer radial direction and the heat radiating member 150 may have a predetermined space formed therebetween, and the space may be filled with the insulating resin 190.

That is, the insulating resin 190 may fill the space between the external lead 124 and the heat radiating member 150 and seal a portion of the external lead 124.

The insulating resin 190 may be formed of a gel-type silicon resin, an epoxy resin, or the like, and may be in a liquid state at the time of being filled in the space, while being cured after being filled, thereby being maintained to have a predetermined form.

As shown in FIG. 7, the semiconductor package 700 according to the sixth embodiment of the present invention may further include a support part 192 in order to fill the liquid-state insulating resin 190.

The support part 192 may be provided outwardly of the external lead 124 in the radial direction so as to maintain a predetermined interval between the support part 192 and the external lead 124, and the space formed between the external lead 124 and the heat radiating member 150 may be filled with the liquid-state insulating resin 190.

Due to the support part 192, the liquid-state insulating resin 190 may be provided to have a predetermined form even before being cured.

Here, referring to FIG. 8, the insulating resin 190 may entirely seal the molded portion 140 while allowing a portion of the external lead 124 to protrude therefrom, as well as the space formed between the external lead 124 and the heat radiating member 150.

Since the liquid-state insulating resin 190 is used to fill the space, it may be easily filled in the space using the support part 192 even after the semiconductor package 600 is completely formed, whereby the insulation characteristics of the semiconductor package 600 may be improved.

The insulating resin 190 is inserted between the external lead 124 and the heat radiating member 150 and seals at least a portion of the external lead 124, whereby the insulation characteristics may be secured at a distance shorter than the insulation clearance distance D and the insulation creepage distance S defined by a rated voltage.

As set forth above, a semiconductor package according to embodiments of the present invention can secure insulation characteristics at a distance shorter than an isolation distance defined by a rated voltage without the formation of a down-set in a lead frame or an increase in the size of the semiconductor package. Therefore, the semiconductor package can be miniaturized, a material cost thereof may be reduced, and a heat radiating structure can be simply designed and mounted.

The high power semiconductor package according to the related art can not secure a sufficient isolation distance, such that it may not be industrially applied. However, the semiconductor package according to the embodiments of present invention has superior insulation characteristics so that it may be industrially applied.

While the present invention has been shown and described in connection with the embodiments, it will be apparent to those skilled in the art that modifications and variations can be made without departing from the spirit and scope of the invention as defined by the appended claims.

What is claimed is:

1. A semiconductor package comprising:
an internal lead having at least one electronic component mounted on a surface thereof;
a heat sink disposed below the internal lead;
a molded portion sealing the at least one electronic component, the internal lead and the heat sink;
an external lead extended from the internal lead and protruding outwardly from the molded portion in a radial direction;
a heat radiating member attached to the heat sink and a surface of the molded portion; and
an insulating coating film formed on a surface of the external lead.

2. The semiconductor package of claim 1, wherein the external lead is bent and extended upwardly at an end thereof, protruding outwardly from the molded portion in the radial direction.

3. The semiconductor package of claim 1, wherein the insulating coating film is formed on the surface of the external lead except for portions thereof mounted on an external substrate.

4. The semiconductor package of claim 1, wherein the surface of the molded portion to which the heat radiating member is attached is provided with a concavo-convex portion.

5. The semiconductor package of claim 1, wherein a surface of the heat radiating member facing the external lead is provided with an insulating sheet.

6. The semiconductor package of claim 1, wherein the insulating coating film is formed on a portion of the surface of the external lead facing the heat radiating member.

7. The semiconductor package of claim 1, wherein the heat radiating member has a surface area larger than that of the heat sink.

8. The semiconductor package of claim 1, wherein the insulating coating film and the heat radiating member have an insulating spacer provided therebetween.

9. A semiconductor package comprising:
an internal lead having at least one electronic component mounted on a surface thereof;
a heat sink disposed below the internal lead;
a molded portion sealing the at least one electronic component, the internal lead and the heat sink;
an external lead extended from the internal lead and protruding outwardly from the molded portion in a radial direction;
a heat radiating member attached to the heat sink and the molded portion; and
an insulating resin provided between the external lead and the heat radiating member and sealing a portion of the external lead.

10. A semiconductor package comprising:
an internal lead having at least one electronic component mounted on a surface thereof;
a heat sink disposed below the internal lead;
a molded portion sealing the at least one electronic component, the internal lead and the heat sink;
an external lead extended from the internal lead and protruding outwardly from the molded portion in a radial direction;
a heat radiating member attached to the heat sink and the molded portion; and
an insulating resin entirely sealing the molded portion while allowing a portion of the external lead to protrude therefrom.
